(19) United States
(12) Patent Application Publication
(10) Pub. No.: US 2018/0076072 A1
(43) Pub. Date: Mar. 15, 2018

(54) AIR BLOW FOR SEMICONDUCTOR WAFERS IN A VACUUM SEMICONDUCTOR WAFER LAMINATOR SYSTEM

(71) Applicant: TEXAS INSTRUMENTS INCORPORATED, Dallas, TX (US)

(72) Inventors: Connie Alagadan ESTERON, Pampanga (PH); Dolores Babaran MILO, Baguio City (PH)

(21) Appl. No.: 15/261,587

(22) Filed: Sep. 9, 2016

(51) Int. Cl. H01L 21/673; H01L 21/687; H01L 21/683

(52) U.S. Cl. CPC H01L 21/67389; H01L 21/6836; H01L 21/68707

(57) ABSTRACT

A vacuum semiconductor wafer laminator system. The system comprises a fan, a first outer air duct coupled to the fan and configured to direct air blown by the fan towards a first side of a semiconductor wafer box, a second outer air duct coupled to the fan and configured to direct air blown by the fan towards a second opposing side of the wafer box, a first inner air duct coupled to the fan and configured to direct air blown by the fan towards the first side of the wafer box, a second inner air duct coupled to the fan an configured to direct air blown by the fan towards the second side of the wafer box, and a robot arm configured to pick up a semiconductor wafer from the wafer box and place the semiconductor wafer on a dicing tape.

### BACKGROUND

Semiconductor devices are used in a great variety of devices and equipment in the modern world and serve many useful purposes. Multiple semiconductor devices may be manufactured or fabricated on a single semiconductor wafer and then sawed into individual die. The processes of fabricating semiconductor devices, handling semiconductor wafers, and mounting semiconductor die are highly automated processes. Stiff competition among semiconductor manufacturers leads to steady improvements in handling processes, increases in yields, and reductions in wastage.

### BRIEF DESCRIPTION OF THE DRAWINGS

For a detailed description of various examples, reference will now be made to the accompanying drawings in which:

FIG. 1 shows a vacuum semiconductor wafer laminator system in accordance with various examples;

FIG. 2 shows a wafer-interleaf packaging sequence in accordance with various examples; and

FIG. 3 shows a method in accordance with various examples.

### DETAILED DESCRIPTION

Certain terms are used throughout the following description and claims to refer to particular system components. As one skilled in the art will appreciate, different companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct wired or wireless connection. Thus, if a first device couples to a second device, that connection may be through a direct connection or through an indirect connection via other devices and connections.

The present disclosure teaches a vacuum semiconductor wafer laminator system that uses an air blow system to reduce the incidence of semiconductor wafer wastage when interleafs are lifted off a stack of semiconductor wafers, an adjacent semiconductor wafer adheres to the lifted interleaf by static electric force, and the semiconductor wafer falls onto the floor and breaks. The interleafs may comprise separator sheets or other types of separator mechanisms placed between, on top of, or below the semiconductor wafers to protect the individual wafers. The disclosed air blow may be selectively turned on or air ducts are opened to direct air towards the stack of semiconductor wafers when a wafer is picked up, whereby an interleaf located below the lifted wafer is disturbed and at least partially decoupled from the semiconductor wafer beneath the disturbed interleaf. This process of disturbing the interleaf may be envisioned as ruffling or waving the interleaf at least partially without blowing it completely out of a semiconductor wafer stack receiving box or receiving cassette. The disclosed air blow may be selectively turned off or associated air ducts closed after the semiconductor wafer is lifted. In an embodiment, the disclosed air blow may be selectively turned off or associated air ducts closed while the lifted semiconductor wafer is lifted above the below interleaf but the lifted semiconductor wafer remains inside of the box or cassette, whereby the interleaf may be prevented from blowing out of the box or cassette.

Portions of the disclosed air blow are located close to the semiconductor wafer box and/or the semiconductor wafer stack. Additionally, portions of the disclosed air blow duct may be located low and/or close to the bottom of the semiconductor wafer box, whereby to better interact with the specific last few semiconductor wafers and interleaves in a stack which are particularly susceptible to the unintentional lifting by static electric attractive force. A vacuum semiconductor wafer laminator system may be used for a variety of purposes. For example, a vacuum semiconductor wafer laminator system may be used to attach a protective tape to a fabrication side of the wafer during grinding of the opposing side of the wafer. Alternatively, a vacuum semiconductor wafer laminator system may be used to attach a slicing die tape to the semiconductor wafer prior to slicing or sawing the processed semiconductor wafer into dies. A vacuum laminator system may be used to attach thin wafers with ring support at wafer edge inside a vacuum chamber.

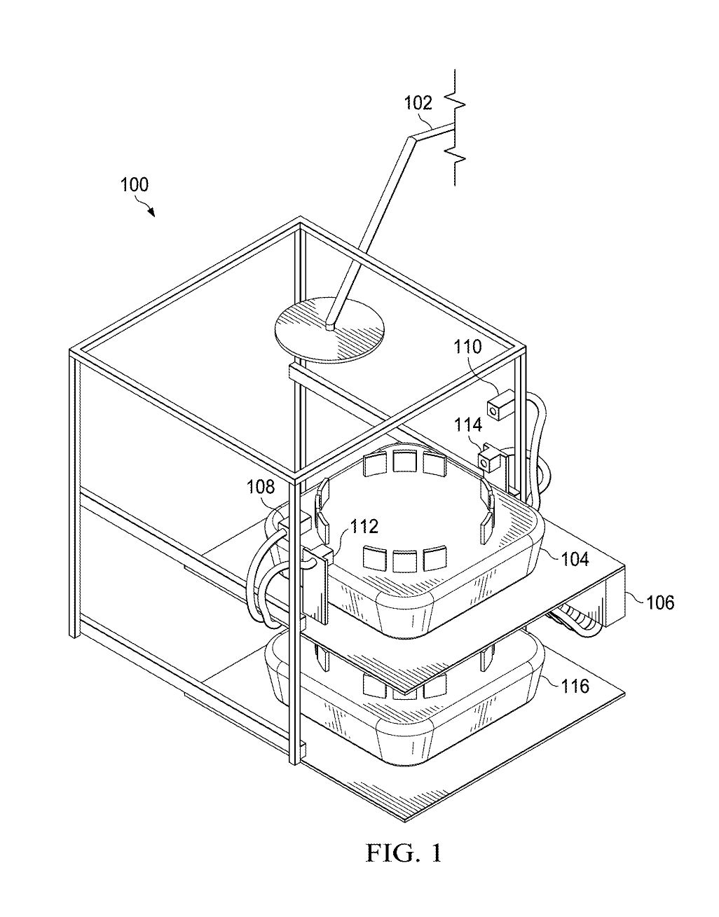

FIG. 1 shows a vacuum semiconductor wafer laminator system 100 according to an embodiment of the disclosure. The vacuum laminator system 100 or machine may be used to pick up thin semiconductor wafers from a wafer box and laminate the wafers on a dicing tape and flex frame, using at least a partial vacuum to pull the dicing tape to the surface of the semiconductor wafer, in preparation for further processing, for example for sawing into separate dies. It is understood that some components of the vacuum laminator system 100 are not illustrated in order to focus on specific components of interest to the present disclosure. Additionally, it is understood that the illustration in FIG. 1 is not intended to represent dimensionally specific relationships among components, except as stipulated herein.

In an embodiment, the vacuum semiconductor wafer laminator system 100 comprises a robot arm 102, a fan 106 or blower, a first outer air duct 108, a second outer air duct 110, a first inner air duct 112, and a second inner air duct 114. In an embodiment, the system 100 may comprise a plurality of fans 106, for example a first fan 106 that provides blown air to the first and second outer air ducts 108, 110 and a second fan 106 that provides blown air to the first and second inner air ducts 112, 114. Alternatively, each air duct 108, 110, 112, 114 may be associated with a different fan 106.

It is understood that in some embodiments the configuration of ducts may be different. For example, in an embodiment, there may be two outer air ducts 108, 110 and a single inner air duct (one of 112, 114). For example, in an embodiment, there may be one outer air duct (one of 108, 110) and a single inner air duct (one of 112, 114). In an embodiment, there may be no outer air ducts (neither of 108, 110) and a single inner air duct (one of 112, 114) or two inner air ducts 112, 114. These different embodiments may provide the same or some of the benefits of disturbing or ruffling the interleaf below a semiconductor being lifted by the robot arm 102 and therefore reduce the probability that the wafer below the interleaf will be inadvertently and unintentionally lifted with the interleaf and fall and break.

The first outer air duct 108 and the first inner air duct 112 are each configured to direct air blown by the fan 106 towards a first side (a left side as illustrated in FIG. 1) of the wafer box 104 when the wafer box is installed into or positioned within the machine 100 (e.g., air blown by the fan 106 when the ducts 108, 112 are selected open and/or when the fan 106 is turned on). Similarly, the second outer air duct 110 and the second inner air duct 114 are each configured to direct air blown by the fan 106 towards a second side (a right side as illustrated in FIG. 1) of the wafer box 104 when the wafer box 104 is installed into or positioned within the machine 100 (e.g., air blown by the fan 106 when ducts 110, 114, are selected open and/or when the fan 106 is turned on). The first inner air duct 112 and the second inner air duct 114 may be configured and/or located to blow air (i.e., air blown by the fan 106) in a plane parallel to the plane of wafers in the wafer box 104 and towards the wafer box 104, for example towards a center vertical axis of the wafer box 104. Alternatively, the first inner air duct 112 and the second inner air duct 114 may be configured and/or located to blow air slightly downwards towards the center vertical axis of the wafer box 104, for example at an angle of about 10 degrees with respect to a plane of wafers in the wafer box 104.

It is understood that valves or baffles may be installed in one or more of the air ducts 108, 110, 112, 114. An air duct 108, 110, 112, 114 having a valve or baffle may be selected open or selected closed by opening or closing the valve or baffle respectively, thereby promoting or prohibiting the flow of air blown by the fan 106 out of the duct. Alternatively, the fan 106 may be selected on or off, thereby promoting or prohibiting the flow of blown air through the ducts 108, 110, 112, 114. An automation processor of the system 100 may control the valve or baffle positions and/or the on or off status of the fan 106 as it sequences processing of semiconductor wafers and interleafs from the wafer box 104.

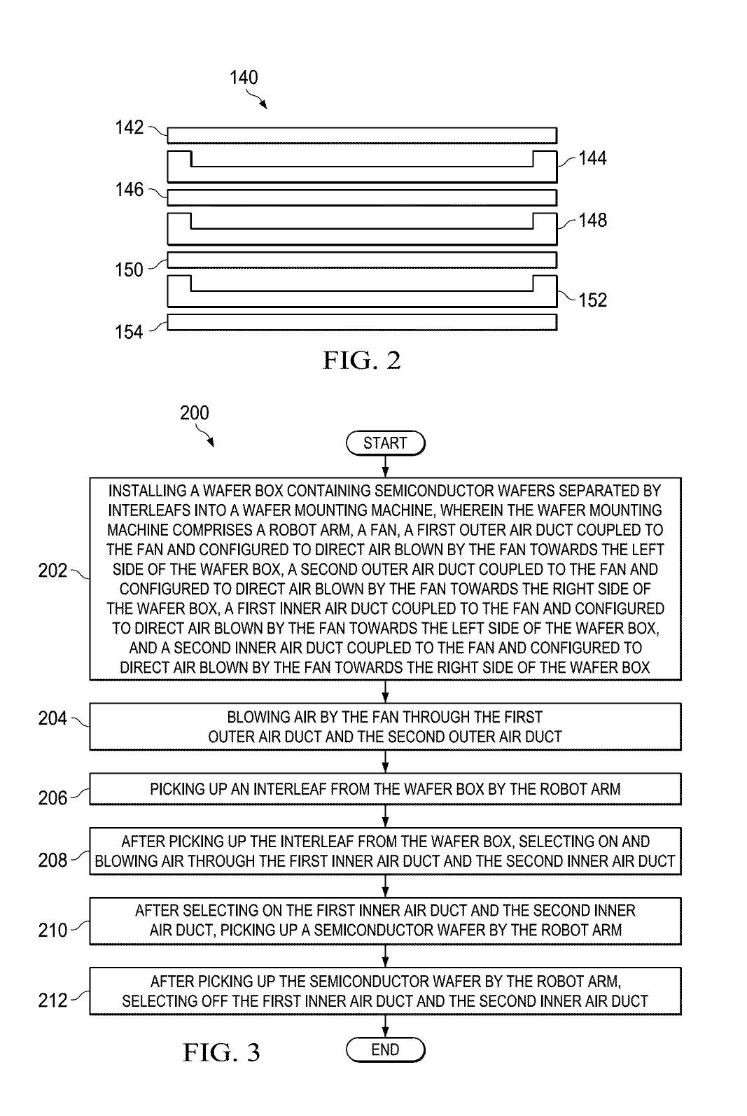

During operation of the vacuum laminator system 100, a wafer box 104 containing a package of wafers and interleafs (i.e., a wafer-interleaf packaging sequence such as is illustrated in FIG. 2) may be installed to be processed. During operation of the vacuum laminator system 100, an interleaf box 116 may be inserted to receive interleafs removed from the wafer box 104 by the robot arm 102. For example, a human operator may install the interleaf box 116 into the system 100.

FIG. 2 shows a wafer-interleaf packaging sequence 140 according to an embodiment of the disclosure. In an embodiment, a wafer-interleaf package comprises a sequence of semiconductor wafers separated by interleafs. The interleafs may comprise separator sheets or other types of separator mechanisms. As illustrated, the wafer-interleaf packaging sequence 140 comprises a first interleaf 142, a first semiconductor wafer 144, a second interleaf 146, a second semiconductor wafer 148, a third interleaf 150, a third semiconductor wafer 152, and a fourth interleaf 154. In an embodiment the packaging sequence 140 may comprise any number of interleafs and semiconductor wafers. In an embodiment, the packaging sequence 140 comprises about twenty-five semiconductor wafers intercalated by interleafs. In an embodiment, the bottom of the packaging sequence 140 may comprise one or more plastic plates (not shown) and one or more sponges (not shown) to provide mechanical support and cushioning to the semiconductor wafers.

When the system 100 is operated, the wafer-interleaf packaging sequence 140 may be installed into the wafer box 104 and the wafer box 104 may be inserted or placed on or in the vacuum laminator system 100. The robot arm 102 may lift off the first interleaf 142 from the packaging sequence 140 and place it in the interleaf box 116. The robot arm 102 may then lift off the first semiconductor wafer 144 from the packaging sequence 140, place the wafer 144 on a piece of dicing tape, and laminate the wafer 144 to the dicing tape. In an embodiment, the system 100 may laminate the wafer 144 to both the dicing tape and a flex frame. The robot arm 102 and other components of the system 100 may be controlled by a logic controller 118. The logic controller 118 may be one or more of a central processing unit (CPU), a digital signal processor (DSP), a microprocessor (MPU), a field programmable gate array (FPGA), a complex programmable logic device (CPLD), an application specific integrated circuit (ASIC), a microcontroller (MCU), or other semiconductor logic processor. The controller 118 may receive inputs from sensors (not shown) of the system 100 that indicate positions of the robot arm 102, position of the wafer box 104, location of top of the stack of semiconductor wafers and/or interleafs in the wafer box 104, positions of air valves, and other physical parameters of the system 100.

As the robot arm 102 lifts the semiconductor wafer 144, the fan 106 blows air through the ducts 108, 110, 112, 114. In an embodiment, mechanical measurement through a regulator may be about 0.25 MPa (megaPascal) to about 0.45 MPa, but in other embodiments a different air flow and/or air pressure differential may be employed. The blown air promotes separation between the interleafs and the semiconductor wafers. Sometimes vacuum laminator machines experience a problem where a semiconductor wafer adheres by action of static electric force (and/or by action of partial vacuum) to the interleaf immediately above it as the robot arm 102 lifts the interleaf, by action of static electric force, and the inadvertently lifted wafer falls to the floor and break, causing wastage and lowering yield. This problem may occur when processing thin semiconductor wafers, such as wafers about 2 mils (a ‘mil’ is 1/1000th of an inch) thick. Additionally, the problem typically occurs when processing the bottom few wafers of a packaging sequence, for example the bottom five wafers from a stack of twenty-five wafers. By increasing the amount of blown air incident on the wafer interleaf packaging sequence 140, using the air blow features disclosed herein, the tendency of the wafer below the lifted interleaf to adhere to the lifted interleaf and fall to the floor is diminished. For example, the blown air from the inner ducts 112, 114 may cause the top interleaf to be disturbed, to flutter, to wave, and thereby decrease the adherence and/or static electric attraction between the fluttering interleaf and the wafer located below the fluttering interleaf.

In an embodiment, the inner ducts 112, 114 are less than about 40 mm away from the wafer box 104. The distance D₁ from the ducts 112, 114 to the wafer box 104 may be measured from the outlet of the ducts 112, 114 to the proximate edge of the wafer box 104. For example, the first inner air duct 112 is less than 40 mm away from the left side of the wafer box 104 and blows air towards a left side of the wafer box 104 and the second inner air duct 114 is less than 40 mm away from the right side of the wafer box 104 and blows air towards a right side of the wafer box 104, when the wafer box 104 is installed on the machine 100. In an embodiment, the inner ducts 112, 114 are at least 10 mm away from the wafer box 104. In an embodiment, the inner ducts 112, 114 are at least 20 mm away from the wafer box 104.

In an embodiment, the outer ducts 108, 110 may be located at least 65 mm away from the wafer box 104 when it is installed on the machine. The distance D₂ from the ducts 108, 110 to the wafer box 104 may be measured from the outlet of the ducts 108, 110 to the proximate edge of the wafer box 104. For example the first outer air duct is at least 65 mm away from the left side of the wafer box 104 and the second outer air duct is at least 65 mm away from the right side of the wafer box 104. In an embodiment, the outer ducts 108, 110 are less than 130 mm away from the wafer box 104. In an embodiment, the outer ducts 108, 110 are less than 90 mm away from the wafer box 104.

In an embodiment, the inner ducts 112, 114 may be selected open when the robot arm 102 is picking up a semiconductor wafer and selected closed when the robot arm 102 is picking up an interleaf. In an embodiment, the system 100 may comprise a first air valve or baffle located in the first inner duct 112 and a second air valve or baffle located in the second inner duct 114 that can be opened or closed by the controller 118. Said in other words, the controller 118 may command the first and second valves open and closed. Alternatively, the controller 118 may turn the fan 106 on when the robot arm 102 is picking up a semiconductor wafer and turn the fan 106 off when the robot arm 102 is picking up an interleaf.

In an embodiment, the outer ducts 108, 110 may be selected open when the robot arm 102 is picking up a semiconductor wafer and selected closed when the robot arm 102 is picking up an interleaf. In an embodiment, the system 100 may comprise a third air valve or baffle located in the first outer duct 108 and a fourth air valve or baffle located in the second outer duct 110 that can be opened or closed by the controller 118.

In an embodiment, the wafers in the wafer box 104 are 200 mm in diameter. In an embodiment, the wafers in the wafer box 104 are about 2 mils thick (as measured at an inner portion of the wafer). In an embodiment, the wafers in the wafer box are TAIKO wafers, for example wafers with a thicker outer edge ring (e.g., where the outer edge of the TAIKO wafer is substantially thicker than the thickness measured inside the outer edge ring). In an embodiment, the wafers are coated with a metal oxide on a top surface of the wafer. In an embodiment, the wafers comprise silicon.

FIG. 3 shows a flow chart of a method 200. At block 202, a wafer box containing semiconductor wafers separated by interleafs is installed into a wafer mounting machine. The wafer mounting machine comprises a robot arm, a fan, a first and a second outer air duct, a first and a second inner air duct. The first outer air duct is coupled to the fan and is configured to direct air blown by the fan towards the left side of the wafer box. The second outer air duct is also coupled to the fan and is configured to direct air blown by the fan towards the right side of the wafer box. The first inner air duct is coupled to the fan and is configured to direct air blown by the fan towards the left side of the wafer box. The second inner air duct is also coupled to the fan and is configured to direct air blown by the fan towards the right side of the wafer box

At block 204, the fan blows air through the first outer air duct and the second outer air duct. In an embodiment, the fan blows air through the first and second outer air ducts continuously while the wafer box is installed into the wafer mounting machine. Alternatively, the air is blown by the first and second outer air ducts only when the robot arm is lifting a wafer from the wafer box. At block 206, the robot arm picks up an interleaf from the wafer box. At block 208, after picking up the interleaf from the wafer box, the process 200 comprises selecting on and blowing air through the first inner air duct and the second inner air duct toward the wafer box. At block 210, after selecting on the first inner air duct and the second inner air duct, the robot arm picks up a semiconductor wafer. At block 212, after picking up the semiconductor wafer by the robot arm, the process comprises selecting off the first inner air duct and the second inner air duct.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A vacuum semiconductor wafer laminator system, comprising:
a fan;
a first outer air duct coupled to the fan and configured to direct air blown by the fan towards a first side of a semiconductor wafer box;
a second outer air duct coupled to the fan and configured to direct air blown by the fan towards a second opposed side of the wafer box;
a first inner air duct coupled to the fan and configured to direct air blown by the fan towards the first side of the wafer box;
a second inner air duct coupled to the fan and configured to direct air blown by the fan towards the second side of the wafer box, where the first and second inner ducts are closer to the wafer box than the first and second outer ducts; and
a robot arm configured to pick up a semiconductor wafer from the wafer box.

2. The system of claim 1, wherein the robot arm is configured both to pick up a semiconductor wafer from a wafer-interleaf packaging sequence located within a wafer box loaded into the vacuum semiconductor wafer laminator system and to place the semiconductor wafer on a dicing tape, wherein the wafer-interleaf packaging sequence comprises a plurality of semiconductor wafers separated by interleafs, wherein the air directed by the first inner air duct and the air directed by the second inner air duct prevent adherence of a semiconductor wafer to an underside of an interleaf by influence of static electricity when the robot arm picks up the interleaf from the wafer box, whereby dropping and breaking semiconductor wafers at a bottom of the wafer box is avoided.

3. The system of claim 1, wherein the first inner air duct and the second inner air duct are selected on during robot arm pick up of the semiconductor wafer and are selected off during robot arm pick up of an interleaf.

4. The system of claim 3 further comprising a logic controller, wherein the first inner air duct comprises a first air valve, the second inner air duct comprises a second air valve, and the controller commands the first and second valve open during robot arm pick up of the semiconductor wafer and commands the first and second valve closed during pick up of the interleaf.

5. The system of claim 1, wherein an outlet of the first inner air duct is located more than 10 mm but less than 40 mm away from the first side of the wafer box and an outlet of the second inner air duct is located more than 10 mm but less than 40 mm away from the second side of the wafer box.

6. The system of claim 5, wherein an outlet of the first outer air duct is located more than 65 mm but less than 130 mm away from the first side of the wafer box and an outlet of the second outer air duct is located more than 65 mm but less than 130 mm away from the second side of the wafer box.

7. The system of claim 1, wherein the robot arm is configured to pick up a 200 mm diameter semiconductor wafer that is about 2 mils thick in an inner portion of the wafer.

8. A method of semiconductor wafer pick up from a wafer box during vacuum lamination of a semiconductor wafer on a dicing tape, comprising:
installing a wafer box containing semiconductor wafers separated by interleafs into a vacuum semiconductor wafer laminator system, wherein the vacuum semiconductor wafer laminator system comprises a robot arm, a fan, a first outer air duct coupled to the fan and configured to direct air blown by the fan towards a first side of the wafer box, a second outer air duct coupled to the fan and configured to direct air blown by the fan towards a second opposing side of the wafer box, a first inner air duct coupled to the fan and configured to direct air blown by the fan towards the first side of the wafer box, and a second inner air duct coupled to the fan and configured to direct air blown by the fan towards the second side of the wafer box, where the first and second inner ducts are closer to the wafer box than the first and second outer ducts;
blowing air by the fan through the first outer air duct and the second outer air duct;
picking up an interleaf from the wafer box by the robot arm;
after picking up the interleaf from the wafer box, selecting on and blowing air through the first inner air duct and the second inner air duct;
after selecting on the first inner air duct and the second inner air duct, picking up a semiconductor wafer by the robot arm; and
after picking up the semiconductor wafer by the robot arm, selecting off the first inner air duct and the second inner air duct.

9. The method of claim 8, wherein the semiconductor wafers contained in the wafer box are 200 mm diameter wafers.

10. The method of claim 9, wherein the semiconductor wafers contained in the wafer box are 2 mils thick wafers.

11. The method of claim 10, wherein the semiconductor wafers contained in the wafer box are TAIKO wafers.

12. The method of claim 8 further comprising placing the semiconductor wafer picked up by the robot arm on a dicing tape by the robot arm.

13. The method of claim 12, wherein the robot arm further laminates the semiconductor wafer to the dicing tape and a flex frame.

14. The method of claim 8 further comprising placing the interleaf picked up by the robot arm from the wafer box into an interleaf box by the robot arm before picking up the semiconductor wafer by the robot arm.

15. A vacuum semiconductor wafer laminator system, comprising:
a fan;
a first outer air duct coupled to the fan and configured to direct air blown by the fan towards a first side of a wafer box, where the wafer box is configured to hold a stack semiconductor wafers separated by interleafs;
a first inner air duct coupled to the fan and configured to direct air blown by the fan towards one of the first side or a second opposing side of the wafer box, where the first inner air duct is located closer to the wafer box than the first outer air duct; and
a robot arm configured to pick up a semiconductor wafer from the wafer box and place the semiconductor wafer on a dicing tape.

16. The system of claim 15 further comprising a second inner air duct coupled to the fan and configured to direct air blown by the fan towards the second opposing side of the wafer box, wherein the first inner air duct is configured to direct air blown by the fan towards the first side.

17. The system of claim 15 further comprising a second outer air duct coupled to the fan and configured to direct air blown by the fan towards a second opposing side of the wafer box.

18. The system of claim 15, wherein the wafer box is configured to hold a stack of 200 mm semiconductor wafers separated by interleafs and where the outlet of the first outer air duct is located at least 65 mm from the first side of the wafer box.

19. The system of claim 18, wherein the outlet of the first inner air duct is located less than about 40 mm from the first side of the wafer box; and

20. The system of claim 15, wherein the semiconductor wafers are 2 mils thick in an inner portion of the wafers.
